(19) United States
(12) Patent Application Publication
(10) Pub. No.: US 2009/0072868 A1
(43) Pub. Date: Mar. 19, 2009

(54) WIDEBAND TRACK-AND-HOLD AMPLIFIER

(75) Inventors: Michael Byung Choi, Seoul (KR); Hong-rak Son, Hwaseong-si (KR); Jung-eun Lee, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/104,827

(22) Filed: Apr. 17, 2008

Related U.S. Application Data
(60) Provisional application No. 60/972,848, filed on Sep. 17, 2007.

(30) Foreign Application Priority Data
Nov. 21, 2007 (KR) 10-2007-0119358

(51) Int. Cl. G11C 27/02

(52) U.S. Cl. 327/94

(57) ABSTRACT

A wideband track-and-hold amplifier is provided. The wideband track-and-hold amplifier is provided in front of an analog-to-digital converter, receives and samples an analog signal, and transfers the sampled signal to the analog-to-digital converter, wherein an output load unit having an inductance component is connected to an input terminal of the analog-to-digital converter. Therefore, it is possible to compensate for a high capacitance component of an analog-to-digital converter, to increase the bandwidth of an output signal, and to improve system linearity.

### CROSS REFERENCE TO RELATED APPLICATIONS

This application claims priority from U.S. Provisional Patent Application No. 60/972,848, filed on Sep. 17, 2007, and Korean Patent Application No. 10-2007-0119358, filed on Nov. 21, 2007, the disclosures of which are incorporated herein in their entireties by reference.

### BACKGROUND OF THE INVENTION

1. Field of the Invention

The present invention relates to a track-and-hold amplifier, and more particularly, to a wideband track-and-hold amplifier which is disposed in front of a high-speed analog-to-digital converter and which can process a wideband signal.

2. Description of the Related Art

An analog-to-digital converter is an electric/electronic device for converting analog signals into digital signals, without losing original data carried by the analog signals.

The reason analog signals are converted into digital signals is because noise removal from digital signals is easier to perform than noise removal from analog signals when processing signals, and transmitting digital signals is more efficient than transmitting analog signals. Accordingly, the latest electronic devices employ a method of processing digital signals. A representative analog-to-digital converter is a flash analog-to-digital converter. In the flash analog-to-digital converter, a plurality of comparators are arranged in parallel to each other in order to simultaneously convert an input analog signal into a digital signal. For example, an 8-bit flash analog-to-digital converter includes 255 comparators, compares an input voltage with reference voltages, using the 255 comparators, to output an output signal, and decodes the output signal into a binary number. The flash analog-to-digital converter is expensive because it uses a plurality of comparators, however, it is widely used because it allows high-speed processing.

Meanwhile, a track-and-hold amplifier is connected to an input terminal of an analog-to-digital converter. The track-and-hold amplifier determines a voltage level of an analog signal when sampling the analog signal, and maintains the voltage level for a predetermined period of time so that all comparators can read the same analog signal value. In other words, the track-and-hold amplifier performs sampling, separately from quantization, and enables the analog-to-digital converter, which is connected to the output of the track-and-hold amplifier, to accurately convert an analog signal into a digital signal.

For example, in a track mode, the track-and-hold amplifier applies an output signal which is the same as an input signal to the analog-to-digital converter, and in a hold mode, maintains the voltage level of the output signal determined in the track mode although the input signal changes.

Also, the track-and-hold amplifier includes a predetermined buffer circuit in order to drive a capacitive load of a capacitance component of the analog-to-digital converter. The buffer circuit may be a source follower where a plurality of input MOSFETs and a plurality of current source MOSFETs are connected in series with each other.

However, recently, along with the development of technologies, since the output impedance of a current source MOSFET has become low, it has become difficult to maintain the current of the current source MOSFET at a constant value. Accordingly, a situation where linearity between an input signal and an output signal is not maintained frequently occurs, and there is a problem in that a bandwidth of an output signal is reduced.

Also, since the analog-to-digital converter which is connected to the output of the track-and-hold amplifier has a high capacitance component, it is necessary to increase the bias current or the capacity of a MOS transistor to drive the track-and-hold amplifier, which deteriorates linearity and reduces the bandwidth of the output signal.

### SUMMARY OF THE INVENTION

Exemplary embodiments of the present invention provide a wideband track-and-hold amplifier which allows high-speed processing, and satisfies linearity for a wideband input signal.

The wideband track-and-hold amplifier may include a passive track-and-hold switch, a source degeneration structure, and a shunt-peaking inductor.

According to an aspect of the present invention, there is provided a wideband track-and-hold amplifier provided upstream of an analog-to-digital converter, including: a sampling unit which receives and samples an analog signal; a transconductor unit which includes an output terminal connected to the analog-to-digital converter, and which transfers the sampled signal to the analog-to-digital converter; and an output load unit disposed between the transconductor unit and the analog-to-digital converter and which resonates the sampled signal that is to be transferred to the analog-to-digital converter.

The sampling unit may include a PMOS transistor and a hold capacitor, wherein a source of the PMOS transistor is connected to an input terminal to which the analog signal is input, and one end of the hold capacitor is connected to a drain of the PMOS transistor.

The transconductor unit may include a differential amplifier in which two MOS transistors are connected in a source degeneration structure, or may include a differential pair of NMOS transistors whose gates are connected to the sampling unit; and degeneration resistors connected to sources of the differential pair of NMOS transistors. An independent current source may be connected to one end of each degeneration resistor, the independent current source separated from a signal transmission path.

The output load unit may include a peak inductor for resonating the sampled signal to allow wideband signal processing, and may include an output resistor which is connected to the output terminal; and a peak inductor connected in series with the output resistor.

According to another aspect of the present invention, there is provided a wideband track-and-hold amplifier provided upstream of an analog-to-digital converter, including: an input terminal which receives an analog signal; a first MOS transistor, being a P-type MOS transistor, whose source is connected to the input terminal; a hold capacitor which has one end connected to the drain of the first PMOS transistor; a second MOS transistor, being a N-type MOS transistor, whose gate is connected to the drain of the first MOS transistor; an output terminal disposed at the drain of the second MOS transistor and connected to the analog-to-digital converter; and an output load unit connected to the output terminal.

In the second MOS transistor, a differential pair of NMOS transistors may be connected in a source degeneration structure. A source of the second MOS transistor may be connected to a degeneration resistor.

The output load unit may include a peak inductor which resonates a signal that is to be transferred to the analog-to-digital converter to allow wideband processing, and may include: an output resistor which is connected to the output terminal; and a peak inductor connected in series with the output resistor.

Additional aspects of the invention will be set forth in the description which follows, and will be apparent to a certain extent from the description, or may be learned through experience with the invention.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the aspects of the invention.

FIG. 1 is a block diagram of a wideband track-and-hold amplifier according to an embodiment of the present invention; and

FIG. 2 is a circuit diagram of a wideband track-and-hold amplifier according to an embodiment of the present invention.

### DETAILED DESCRIPTION OF EXEMPLARY EMBODIMENTS

The present invention is described more fully hereinafter with reference to the accompanying drawings, in which exemplary embodiments of the invention are shown. This invention may, however, be embodied in many different forms and should not be construed as being limited to the exemplary embodiments set forth herein. Rather, these exemplary embodiments are provided so that this disclosure is thorough, and will fully convey the scope of the invention to those skilled in the art.

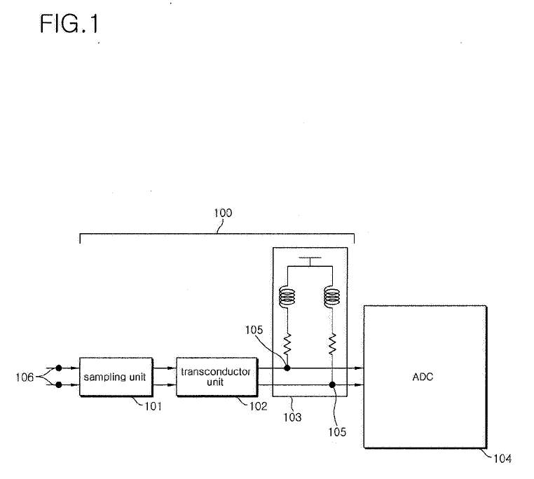

FIG. 1 is a block diagram of a wideband track-and-hold amplifier 100 according to an embodiment of the present invention.

Referring to FIG. 1, the wideband track-and-hold amplifier 100 is disposed in front of an analog-to-digital converter 104. The track-and-hold amplifier 100 samples an analog signal, and transfers the sampled analog signal to an analog-to-digital converter 104. The track-and-hold amplifier 100 maintains a level (for example, a voltage level) of the analog signal when sampling the analog signal so that the components of the analog-to-digital converter 104 can read the same input signal.

The analog-to-digital converter 104 may be a flash type converter where a plurality of comparators are arranged in parallel.

In detail, the track-and-hold amplifier 100 includes a sampling unit 101, a transconductor unit 102, and an output load unit 103.

The sampling unit 101 receives an analog signal from input terminals 106, and samples the analog signal whenever a predetermined period of time has elapsed. The sampling unit 101 includes a switch which operates according to a periodical clock signal, and a capacitor which temporarily stores an input signal. For example, when the clock signal applied to the switch goes high, the switch is turned on and the capacitor is charged to the voltage level of the input signal. When the clock signal goes low, the switch is turned off and the voltage stored in the capacitor is maintained.

The transconductor unit 102, having one end connected to the sampling unit 101, receives the sampled analog signal. The other end of the transconductor unit 102 is an output terminal which is connected to the analog-to-digital converter 104 and through which the sampled analog signal is transferred to the analog-to-digital converter 104. Also, since the output load unit 103 is connected in parallel between the transconductor unit 102 and the analog-to-digital converter 104, the transconductor unit 102 can be connected directly or via the output load unit 103 to the analog-to-digital converter 104. The transconductor unit 102 may be a buffer amplifier, for example, where at least two MOSFETs are connected to each other. The transconductor unit 102 may linearly convert an input voltage value and output a current signal as the result of the conversion.

The output load unit 103 is provided between the transconductor unit 102 and the analog-to-digital converter 104, and is connected to the output terminals of the transconductor unit 102. When the transconductor unit 102 converts an input voltage linearly and outputs a current signal as the result of the conversion through output terminals 105, the current signal at the output terminals 105 is converted into a voltage signal by the output load unit 103 and the voltage signal is input to the analog-to-digital converter 104.

Also, the output load unit 103 includes a predetermined inductance component L to resonate or amplify a signal transferred to the analog-to-digital converter 104. The output load unit 103 may include resistors and inductors which are disposed between the transconductor unit 102 and the analog-to digital converter 104 and connected to the output terminals 105, wherein a resistor and an inductor are serial-connected to each other in pairs. Accordingly, the output load unit 103 is disposed between the transconductor unit 102 and the analog-to-digital converter 104, while being connected to the output terminals 105.

A capacitive load is provided at a part through which a signal is input to the analog-to-digital converter 104. Accordingly, as described above, if an inductive load is provided in front of the analog-to-digital converter 104 (that is, at the output terminals 105), it is possible to increase the bandwidth of an output signal through LC resonance.

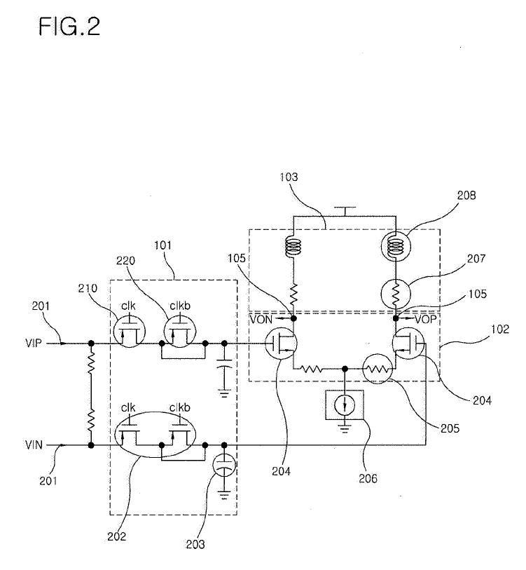

FIG. 2 is a circuit diagram of a wideband track-and-hold amplifier 100 according to an embodiment of the present invention. As described above, the wideband track-and-hold amplifier 100 includes a sampling unit 101, a transconductor unit 102, and an output load unit 103.

In FIG. 2, VIP and VIN represent input signals, and VOP and VON represent output signals. The sampling unit 101 includes a MOS transistor 202 which functions as a switch, and a hold capacitor 203 having one end connected to the MOS transistor 202 and which is charged to a level of the input signal in order to provide the input signal.

The MOS transistor 202 may be a PMOS transistor. An input terminal 201 of the sampling unit 101 into which an analog signal is input is connected to the source of the MOS transistor 202. Also, one end of the hold capacitor 203 is connected to the drain of the PMOS transistor 202, and the other end of the hold capacitor 203 is grounded.

Now, the operation of the sampling unit 101 will be described.

The PMOS transistor 202 includes a first PMOS transistor 210 which is directly connected to the input terminal 201, and a second PMOS transistor 220 between whose source and drain a feed-back path is formed. A clock signal clk and an inverse clock signal clkb are respectively applied to the first PMOS transistor 210 and the second PMOS transistor 220. When the clock signal clk goes high, the first PMOS transistor 210 is turned on and the second PMOS transistor 220 is turned off, so that the input terminal 201 is connected to the hold capacitor 203 and the hold capacitor 203 is charged to an input voltage. The clock signal clkb is an inverse signal of the clock signal clk, and accordingly, the clock signal clkb goes low when the clock signal clk goes high. Then, if the clock signal clk goes low, the PMOS transistor 210 is turned off so that the input terminal 201 is disconnected from the hold capacitor 203. Therefore, although the input voltage changes, the input voltage stored in the hold capacitor 203 is maintained at a constant level.

The transconductor unit 102 includes a differential amplifier in which two MOS transistors are connected in a source degeneration structure. That is, the transconductor unit 102 comprises a differential pair of NMOS transistors 204 whose gates are connected to one end of the hold capacitor 203.

Also, a degeneration resistor 205 is connected to the source of the NMOS transistor 204 so that linearity is ensured during signal transformation. An independent current source, which is separated from a signal transmission path, is connected to one end of the degeneration resistor 205. An output terminal 105, which is connected to the analog-to-digital converter 104 and outputs a signal, is connected to the drain of the NMOS transistor 204.

In an existing track-and-hold amplifier, a source follower buffer consisting of current source MOSFETs is generally used to transfer a signal to the analog-to-digital converter. The source follower buffer, as described above, does not ensure linearity during high-speed operations. In the current embodiment, since the transconductor unit 102 uses the differential pair of NMOS transistors 204 which are connected in the source degeneration structure and the independent current source 206 is separated from the signal transmission path, linearity of a signal outputted from the output terminal 105 is maintained due to the degeneration resistor 205 regardless of the non-linearity of the independent current source 206. Accordingly, the linearity and bandwidth of an output signal can be ensured independently despite the non-linear property of a current source.

The output load unit 103 is connected to the output terminal 105, that is, to the drain of the NMOS transistor 204. Since the output terminals 105 are connected to the analog-to-digital converter 104, the output load unit 103 is disposed between the transconductor unit 102 and the analog-to-digital converter 104, and connected to the output terminals 105.

Also, the output load unit 103 includes an output resistor 207 connected to the drain of the NMOS transistor 204, and a peak inductor 208 connected in series with the output resistor 207. The peak inductor 208 is used to compensate for the high capacitance of the analog-to-digital converter 104, and functions to amplify signals through LC resonance.

That is, since the track-and-hold amplifier 100 includes an inductance component in the output load unit 103 connected to the output terminal 105, the track-and-hold amplifier 100 can perform wideband signal processing unlike an existing track-and-hold amplifier having only a resistance component. By properly adjusting an inductance value of the peak inductor 208 according to its use or purpose, an LC resonance frequency can be adjusted.

As a result, in the wideband track-and-hold amplifier 100 according to the current embodiment of the present invention, it is possible to ensure the linearity of an output signal using the transconductor unit 102 which is in a source degeneration structure having a differential pair of transistors, and improve the bandwidth of the output signal by compensating for a high capacitance component included in the analog-to-digital converter 104 through the output load unit 103 connected to the output terminals 105 and including an inductance component.

It will be apparent to those skilled in the art that various modifications and variations can be made in the present invention without departing from the spirit or scope of the invention. Thus, it is intended that the present invention includes modifications and variations of the invention as described above provided they come within the scope of the appended claims and their equivalents.

What is claimed is:

1. A wideband track-and-hold amplifier provided upstream of an analog-to-digital converter, comprising:
a sampling unit which receives and samples an analog signal;
a transconductor unit which includes an output terminal connected to the analog-to-digital converter, and transfers the sampled signal to the analog-to-digital converter; and
an output load unit disposed between the transconductor unit and the analog-to-digital converter and which resonates the sampled signal that is transferred to the analog-to-digital converter.

2. The wideband track-and-hold amplifier of claim 1, wherein the sampling unit comprises a PMOS transistor and a hold capacitor, and
wherein a source of the PMOS transistor is connected to an input terminal to which the analog signal is input, and one end of the hold capacitor is connected to a drain of the PMOS transistor.

3. The wideband track-and-hold amplifier of claim 1, wherein the transconductor unit comprises a differential amplifier in which two MOS transistors are connected in a source degeneration structure.

4. The wideband track-and-hold amplifier of claim 1, wherein the transconductor unit comprises:
a differential pair of NMOS transistors whose gates are connected to the sampling unit; and
degeneration resistors connected to sources of the differential pair of NMOS transistors.

5. The wideband track-and-hold amplifier of claim 4, wherein an independent current source is connected to one end of each of the degeneration resistors, the independent current source being separated from a signal transmission path.

6. The wideband track-and-hold amplifier of claim 1, where the output load unit comprises a peak inductor which resonates the sampled signal to allow wideband signal processing.

7. The wideband track-and-hold amplifier of claim 1, wherein the output load unit comprises:
an output resistor which is connected to the output terminal; and
a peak inductor connected in series with the output resistor.

8. A wideband track-and-hold amplifier provided upstream of an analog-to-digital converter, comprising:
an input terminal which receives an analog signal;
a first MOS transistor, being a P-type MOS transistor, whose source is connected to the input terminal;
a hold capacitor having one end connected to the drain of the first PMOS transistor;
a second MOS transistor, being a N-type MOS transistor, whose gate is connected to the drain of the first MOS transistor;
an output terminal formed at the drain of the second MOS transistor and connected to the analog-to-digital converter; and
an output load unit connected to the output terminal.

9. The wideband track-and-hold amplifier of claim 8, wherein, in the second MOS transistor, a differential pair of NMOS transistors are connected in a source degeneration structure.

10. The wideband track-and-hold amplifier of claim 8, wherein a source of the second MOS transistor is connected to a degeneration resistor.

11. The wideband track-and-hold amplifier of claim 10, wherein one end of the degeneration resistor is connected to an independent current source which is separated from a signal transmission path.

12. The wideband track-and-hold amplifier of claim 8, wherein the output load unit comprises a peak inductor which resonates a signal that is to be transferred to the analog-to-digital converter to allow wideband processing.

13. The wideband track-and-hold amplifier of claim 8, wherein the output load unit comprises:
an output resistor which is connected to the output terminal; and
a peak inductor connected in series with the output resistor.
